(19) United States
(12) Patent Application Publication
(10) Pub. No.: US 2011/0220012 A1
(43) Pub. Date: Sep. 15, 2011

(54) CRYSTAL GROWTH APPARATUS WITH LOAD-CENTERED APERTURE, AND DEVICE AND METHOD FOR CONTROLLING HEAT EXTRACTION FROM A CRUCIBLE

(75) Inventors: Zhenming Wu, Nashua, NH (US); Dean C. Skelton, Fitzwilliam, NH (US); Brett C. Forlano, Manchester, NH (US)

(73) Assignee: GT SOLAR, INCORPORATED, Merrimack, NH (US)

(21) Appl. No.: 13/046,166

(22) Filed: Mar. 11, 2011

Related U.S. Application Data
(60) Provisional application No. 61/313,347, filed on Mar. 12, 2010.

(51) Int. Cl. C30B 11/02; C01B 33/021; C30B 35/00

(52) U.S. Cl. 117/81; 117/223; 425/470; 264/332; 264/327

(57) ABSTRACT

A crystal growth apparatus includes a crucible arranged on a support mechanism, and at least two plates formed below the support mechanism and movable in a coordinated manner to form a symmetrical aperture centered with respect to an ingot being formed in the crucible, and a drive mechanism for driving the plates with one degree of freedom. The plates open in a plurality of discrete positions to form an aperture that is load centered with respect to the ingot being formed, in order to promote directional solidification of the ingot being formed, and thus achieve a desired convex profile of the ingot.

### CROSS-REFERENCE TO RELATED APPLICATION

This application claims the benefit of copending application U.S. Provisional Application Ser. No. 61/313,347 filed on Mar. 12, 2010, the disclosure of which is expressly incorporated herein by reference in its entirety.

### FIELD OF INVENTION

The present invention relates to furnaces for crystal growth and directional solidification, and more particularly to a crystal growth apparatus having a load-centered aperture, and a device and method for controlling heat extraction from a crucible contained in the crystal growth apparatus.

### BACKGROUND OF THE INVENTION

Directional solidification systems (DSS) are used for the production of silicon ingots, for example, for use in the photovoltaic industry. A DSS furnace can be used for crystal growth and directional solidification of a starting material such as silicon. In DSS processes, silicon feedstock can be melted and directionally solidified in the same furnace. Conventionally, a crucible containing a charge of silicon is placed in a furnace, and at least one heating element is arranged near the crucible.

In directional solidification processes, a volume of silicon feedstock material is melted in a crucible at about its melting point temperature of 1412° C., thus forming a silicon melt. As heat is extracted from the bottom of the crucible, a bottom layer of the silicon melt begins to solidify, and forms a first layer of solid silicon at the bottom of the crucible. As heat is further removed from the bottom of the crucible, the solidified silicon continues to grow. The process continues until substantially the entire volume of the silicon melt is solidified, i.e., an ingot is produced. In this process, the direction of heat extraction is opposite to the direction of silicon growth; that is, as heat is extracted from the bottom of the crucible, solidification of the silicon melt advances toward the top of the crucible. Thus, impurities are “pushed” to the top and edges of the crucible, where solidification is last to occur. Directional solidification can be used as a purification process, i.e., since most impurities are more soluble in liquid than in the solid phase during solidification, impurities will be “pushed” by the solidification front, resulting in a lower concentration of impurities in the ingot that is formed as compared to the feedstock material.

Two typical solid-liquid interfaces may occur in a directional solidification process: a convex profile in which impurities are moved to corners of the silicon ingot, and a concave profile in which impurities are formed at the center and corners of the silicon ingot. A convex profile of the silicon ingot is more desirable, as it can provide maximum usable material of a substantially uniform shape.

German Patent DE 100 21 585 discloses an arrangement for producing a silicon melt, and directionally solidifying the silicon melt, in which a plurality of heating rods are arranged beneath a mold containing the silicon melt, and a cooling facility is arranged below the heating rods and separated from the heating rods by an insulating slide, such that during a solidification phase, the insulating slide is moved in a horizontal direction away from the mold, and radiant heat from the mold is transferred to the cooling facility. According to this German patent, the insulating slide is either open or closed, i.e., closed such that the silicon melt is heated by the heating rods during a heating phase, or open and removed away from the mold during the solidification phase.

U.S. Patent Application Publication US 2009/0280050 to Ravi et al. discloses an apparatus and method for forming a multi-crystalline silicon ingot by directional solidification including the use of horizontally movable heat shields arranged below a crucible, which purportedly results in controlled ingot growth and a convex profile.

According to the various embodiments of the published patent application to Ravi et al., either four independently movable heat shields, or two pivoting and/or overlapping heat shields, are used. However, in each embodiment, a complex control mechanism and/or multiple drive mechanisms are required. In particular, each of the heat shields is independently and separately movable in order to produce an opening of the desired size and/or shape.

It would be desirable to provide a crystal growth apparatus, and a device and method for controlling heat extraction from a crucible contained in the crystal growth apparatus, in which radiant heat from the crucible is allowed to pass through an aperture that can open in varying amounts, and where a simplified drive mechanism is provided for controlling a size of the aperture, such that a silicon melt can be cooled from its bottom center to produce a silicon ingot having a convex profile.

### SUMMARY OF THE INVENTION

A crystal growth apparatus, and a device and method for controlling heat extraction from a crucible contained in the crystal growth apparatus are provided, where the crystal growth apparatus preferably includes at least two plates that move in a coordinated manner to form a symmetrical aperture centered with respect to an ingot being formed in a crucible, and a drive mechanism is provided to drive the plates with one degree of freedom. The plates are arranged to form an aperture that is load centered with respect to the ingot being formed in the crucible, in order to promote directional solidification of the ingot being formed, and thus achieve a desired convex profile of the ingot. The crystal growth apparatus can be a directional solidification furnace in which a charge of silicon is placed in the crucible, and at least one heating element is arranged near the crucible. In particular, the charge can be silicon feedstock, or silicon feedstock with a monocrystalline silicon seed.

A crystal growth apparatus according to the subject invention preferably includes a crucible for receiving a charge; a support mechanism configured to support the crucible; at least one heating element for heating and at least partially melting the charge; and a device for controlling heat extraction from the crucible including at least two plates being movable in a coordinated manner to form a symmetrical aperture substantially centered with respect to an ingot being formed in the crucible, and a drive mechanism configured to drive the at least two plates with a single degree of freedom.

Preferably, the at least two plates are moved at the same rate so as to vary a size, but more preferably not substantially change the shape, of the aperture, where the at least two plates are movable between a fully closed position and a fully open position, and more preferably the at least two plates are movable in a plurality of discrete partially open positions between the fully closed position and the fully open position. Also, the at least two plates can be interlocking, such that the at least two plates are engaged and interlocked in the fully closed position. Further, the at least two plates can be configured to slide toward or away in approximately equal amounts from a bottom center of the crucible. In other words, the aperture formed by the at least two plates preferably is load centered, i.e., the at least two plates are arranged such that their installation center corresponds to a bottom center of the crucible where the ingot is being formed. The at least two plates can form the aperture having a shape selected from at least the following shapes: square, rectangular, circular, parabolic, rhombic, and elliptical, or the shape can be defined by the relationship y=f(x), where x and y refer to distances along an X-axis and Y-axis, respectively. In certain embodiments, the at least two plates include triangular sections that form an aperture having the shape of a square, rectangle, or rhombus. The at least two plates preferably are movable so as to allow passage of radiant heat through the aperture in a controlled manner, and thereby achieve thermal gradient profiles resembling the contour of an ingot being formed.

According to the subject invention, the crucible preferably is contained in a crucible box, which can directly contact the support mechanism. The support mechanism is a block made of graphite or a similar material, and may be formed as a solid block. Alternatively, the block can include a plurality of holes that extend through the block. As a further alternative, the support mechanism can be formed as a plurality of supports, beams, and/or columns.

The crystal growth apparatus of the subject invention optionally can include a heat exchanger arranged in the crystal growth apparatus, where the heat exchanger preferably receives heat radiated from a bottom of the support mechanism. A diffusion plate optionally can be arranged between the support mechanism and the heat exchanger to provide a substantially even temperature distribution.

A device according to the subject invention for controlling heat extraction from a crucible contained in a crystal growth apparatus can include: at least two plates being movable in a coordinated manner to form a symmetrical aperture substantially centered with respect to an ingot being formed in the crucible; and a drive mechanism configured to drive the at least two plates with one degree of freedom.

A method according to the subject invention for controlling heat extraction from a crucible contained in a crystal growth apparatus can include steps of: providing a crucible for receiving a charge; heating and at least partially melting the charge contained in the crucible; providing at least two plates that are movable in a coordinated manner to form a symmetrical aperture substantially centered with respect to an ingot being formed in the crucible; and driving the at least two plates with a single degree of freedom.

Other aspects and embodiments of the invention are discussed below.

### BRIEF DESCRIPTION OF THE DRAWINGS

For a fuller understanding of the nature and desired objects of the present invention, reference is made to the following detailed description taken in conjunction with the accompanying drawing figures wherein like reference character denote corresponding parts throughout the several views and wherein:

FIG. 1 is a perspective view in cross section of a crystal growth apparatus according to the subject invention;

FIG. 2A is a cross-sectional view of a crystal growth apparatus according to the subject invention incorporating a support mechanism of a solid block;

FIG. 2B is a top plan view of the crystal growth apparatus of FIG. 2A;

FIG. 3A is a cross-sectional view of a crystal growth apparatus according to the subject invention incorporating a support mechanism of a plurality of beams;

FIG. 3B is a top plan view of the crystal growth apparatus of FIG. 3A;

FIG. 4A is a cross-sectional view of a crystal growth apparatus according to the subject invention incorporating a support mechanism of a block with a plurality of holes extending through the block;

FIG. 4B is a top plan view of the crystal growth apparatus of FIG. 4A;

FIGS. 5A-5C are perspective views of at least two plates in a fully open position, a partially open position, and a fully closed position, respectively, and configured to form a square aperture;

FIG. 5.1 is an exploded side perspective view of the at least two plates of FIGS. 5A-5C illustrating details of the triangular sections of the at least two plates;

FIG. 6A is a plan view of an ingot formed with a square contour and a square heat transfer path utilizing the plates of FIGS. 5A-5C;

FIGS. 6B-6C are temperature profiles in an X-X section and a Y-Y section, respectively, of the ingot of FIG. 6A;

FIG. 7 is an enlarged schematic view of a temperature profile in an X-Y plane of the ingot of FIG. 6A;

FIGS. 8A-8C are perspective views of two plates in a fully open position, a partially open position, and a fully closed position, respectively, and configured to form a circular aperture in the fully open position;

FIGS. 9A-9C are perspective views of two plates in a fully open position, a partially open position, and a fully closed position, respectively, and configured to form a rectangular aperture;

FIGS. 10A-10C are perspective views of two plates in a fully open position, a partially open position, and a fully closed position, respectively, and configured to form a parabolic aperture;

FIGS. 11A-11C are perspective views of two plates in a fully open position, a partially open position, and a fully closed position, respectively, and configured to form a rhombic aperture;

FIGS. 12A-12C are perspective views of two plates in a fully open position, a partially open position, and a fully closed position, respectively, and configured to form different elliptical aperture shapes in the fully open and partially open positions;

FIGS. 13A-13C are perspective views of two plates in a fully open position, a partially open position, and a fully closed position, respectively, and configured to form a square aperture, according to an alternate embodiment for forming a square aperture;

FIG. 14 is an isolated plan view of a drive mechanism for a crystal growth apparatus according to the subject invention, where two plates are in a fully closed position;

FIG. 15 is an isolated plan view of the drive mechanism of FIG. 14, where the two plates form a square aperture in a partially open position; and

FIG. 16 is an isolated plan view of the drive mechanism of FIG. 14, where the two plates form a square aperture in a fully open position.

### DEFINITIONS

The subject invention is most clearly understood with reference to the following definitions:

As used in the specification and claims, the singular form “a”, “an” and “the” include plural references unless the context clearly dictates otherwise.

A “furnace” or “crystal growth apparatus” as described herein refer to any device or apparatus used to promote crystal growth and/or directional solidification, including but not limited to crystal growth furnaces and directional solidification (DSS) furnaces, where such furnaces may be particularly useful for growing silicon ingots for photovoltaic (PV) and/or semiconductor applications. The term “furnace” also refers to any device used for heating, including those suitable for high temperature applications in which operating temperatures exceed about 1000° C.

### DETAILED DESCRIPTION OF THE INVENTION

A crystal growth apparatus, and a device and method for controlling heat extraction from a crucible contained in the crystal growth apparatus are provided, in which at least two plates are arranged so as to be movable in a coordinated manner to form a symmetrical aperture substantially centered with respect to an ingot being formed in a crucible, and a drive mechanism is configured to drive the at least two plates with one degree of freedom. Preferably, the at least two plates are arranged under the crucible such that an installation center of the at least two plates corresponds to a bottom center of the crucible, and an aperture formed by the at least two plates will be load centered with respect to the ingot being formed in the crucible. According to the subject invention, the aperture is approximately symmetrical, where the opening shape of the aperture can be any of a variety of shapes, depending on the selection of the shape of the at least two plates, where a suitable shape of the aperture can be, for example: square, rectangular, circular, parabolic, rhombic, and elliptical, among other shapes. Also, the aperture optionally can have a nonlinear shape, and can be defined by the relationship y=f(x), where x and y refer to distances along an X-axis and Y-axis, respectively. Further, the aperture can be formed by at least two plates having triangular sections that form an aperture shaped as a square, rectangle, or rhombus. Preferably the at least two plates are moved at the same rate so as to vary a size of the aperture, and more preferably not substantially change the shape of the aperture. The at least two plates can be moved between a fully closed position and a fully open position.

According to the subject invention, the at least two plates are provided in the fully closed position during heating and melting of a charge contained in the crucible of the crystal growth apparatus. The crystal growth apparatus can be a directional solidification furnace in which a charge of silicon is placed in the crucible, and at least one heating element is arranged near the crucible. In particular, the charge can be silicon feedstock, or silicon feedstock with a monocrystalline silicon seed. After heating and melting of the charge, the charge is gradually solidified in the crucible during a solidification phase. During solidification, the at least two plates are moved or stopped at desired positions with selected velocities between and including the fully closed position and the fully open position. Between the fully closed position and the fully open position, the at least two plates can be opened in discrete amounts, such that a plurality of intermediate partially open positions are attainable. By opening the at least two plates gradually, directional solidification is promoted, and the ingot being formed can achieve a desired convex profile. The at least two plates preferably are movable to allow passage of radiant heat through the aperture in a controlled manner, and thereby achieve thermal gradient profiles resembling a contour of the ingot being formed.

Preferably at least two plates are moved to form a desired aperture shape, which can approximate a shape of the ingot being formed in the crucible, and more preferably, only two plates are used. However, it is possible to use more than two plates, for example, by reconfiguring and/or replacing one or more of the plates with multiple plates. Preferably the plates are interlocking and/or overlapping, such that they are configured to be interlocked and engaged in the fully closed position. The interlocking of the at least two plates can occur in a variety of configurations, such as a “sandwich” construction or a “staggered” construction, depending on how the plates are positioned. For example, according to a sandwich construction, a first plate is at least partially received between top and bottom portions of a second plate. According to a staggered construction, first and second plates are arranged in a staggered and overlapping manner with respect to each other.

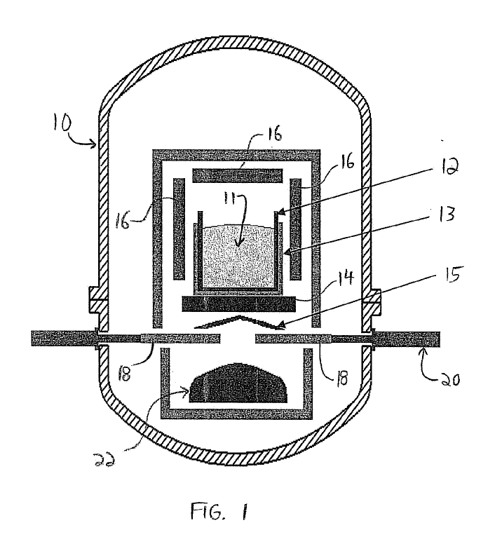

Referring to FIG. 1, a crystal growth apparatus 10 according to the subject invention preferably includes a crucible 12 arranged in a crucible box 13 on a support mechanism 14, and at least one heating element 16 provided in the crystal growth apparatus 10 preferably near the crucible 12 to heat and melt a charge 11 contained in the crucible 12. At least two plates 18 preferably are arranged below the support mechanism 14, and are movable in a coordinated manner to form a symmetrical aperture substantially centered with respect to an ingot being formed from the charge 11 in the crucible 12.

The crucible 12 can be formed with four side plates and one bottom plate, although other arrangements may be suitable. Preferably the crucible 12 is made of fused silica or a suitable substitute material. The crucible 12 preferably is contained in the crucible box 13, which can be made of graphite or a suitable substitute material. The crucible box 13 is supported by the support mechanism 14, such that the support mechanism 14 preferably directly contacts the crucible box 13, which conducts heat from the crucible 12. Preferably a surface area of the support mechanism 14 is greater than or about equal to a surface area of the crucible box 13 and the bottom of the crucible 12, in order to adequately conduct heat from substantially the entire bottom surface of the crucible 12.

As shown in FIG. 1, the heat may be conducted by the support mechanism 14 and radiated through an aperture formed by the at least two plates 18 when the plates are in a partially open or fully open position. Preferably, a diffusion plate 15 made of graphite or a suitable substitute material is arranged between the support mechanism 14 and the at least two plates 18 so as to direct heat through the aperture with a substantially even temperature, where the diffusion plate 15 can serve as a buffer between the support mechanism 14 and a heat exchanger 22, as described herein, when the plates are in a partially open or fully open position. The crystal growth apparatus 10 can be operated with or without the diffusion plate 15.

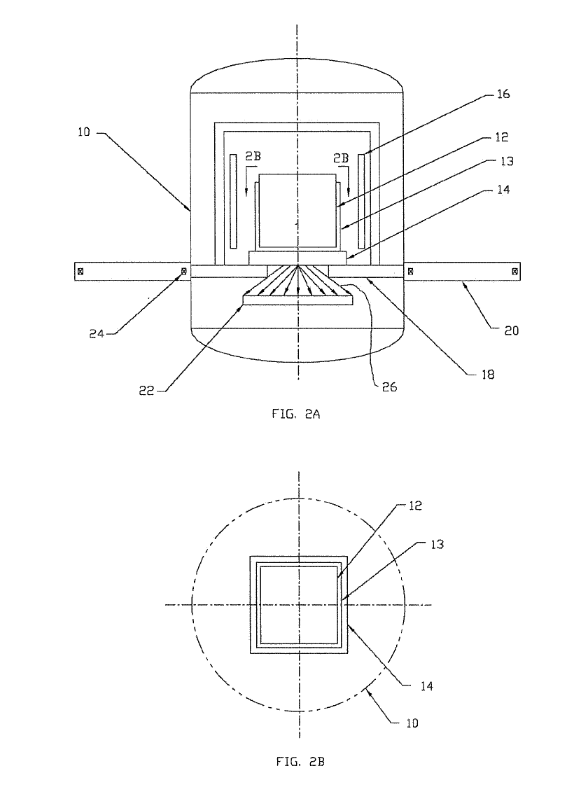

Referring to FIGS. 2A-2B, the support mechanism 14 can be a solid block, for example, made of graphite or similar material. Radiant heat 26 from the support mechanism 14 is directed through the aperture formed by the at least two plates 18, and toward the heat exchanger 22. Referring to FIGS. 1 and 2A-2B, the heat exchanger 22 preferably is arranged so as to extract the heat being radiated by the support mechanism 14. In particular, the radiant heat 26 is received by the heat exchanger 22, where the heat exchanger 22 can pass the heat to a cooling medium such as water.

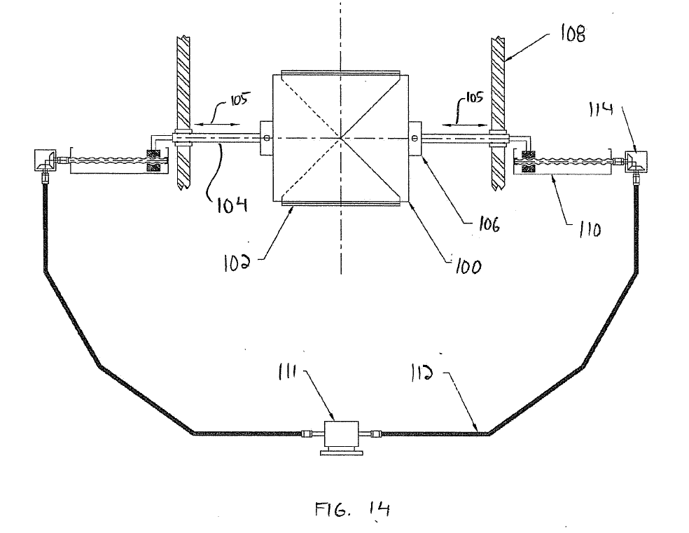

Referring to FIG. 1, a drive mechanism 20 is configured to drive the at least two plates 18 with one degree of freedom (i.e., a single degree of freedom or motion). By driving the at least two plates 18 with one degree of freedom, a simple control mechanism can be used, thus achieving two-dimensional increments of displacement for the opening of the aperture formed by the at least two plates 18 with a predetermined relationship of x and y based on the contour of the selected opening shape, such as square, rectangular, circular, parabolic, rhombic, and elliptical, or as defined by y=f(x). For example, the at least two plates 18 can be driven in substantially equal amounts. The drive mechanism 20 is described in greater detail herein with respect to FIGS. 14-16. As shown in FIG. 2A, one or more position sensors 24 can be provided on the drive mechanism 20.

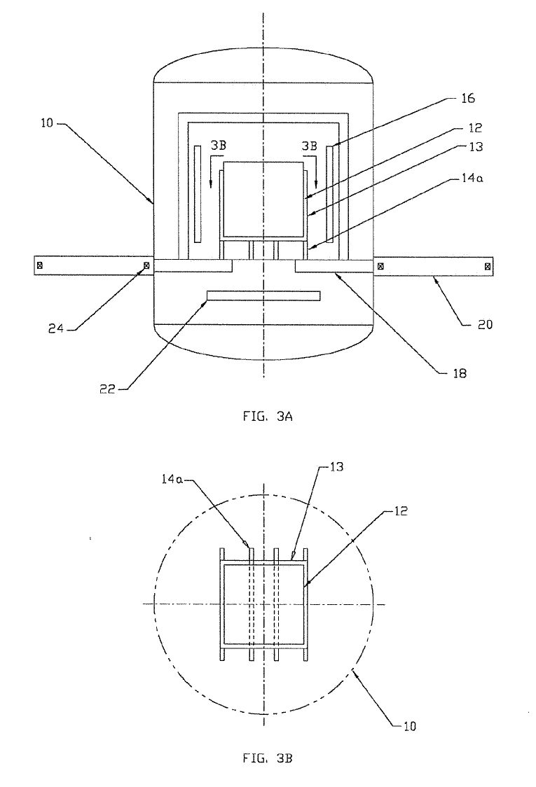

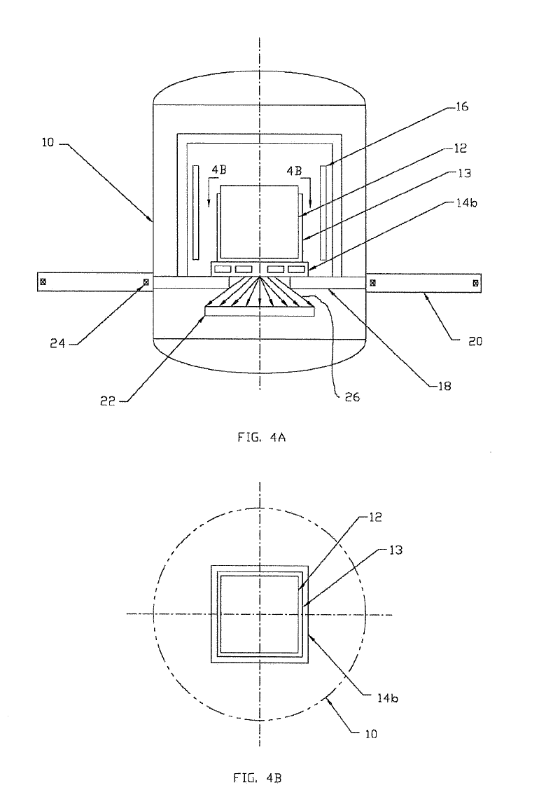

FIGS. 3A-3B and 4A-4B depict alternate support mechanisms according to the subject invention, where the embodiments depicted in FIGS. 3A-3B and 4A-4B, respectively, are substantially similar to the embodiment of FIGS. 2A-2B, except for the support mechanism. Referring to FIGS. 3A-3B, a support mechanism 14a includes a plurality of beams, supports, and/or columns (collectively referred to herein as “beams”). The beams of the support mechanism 14a preferably are spaced apart from each other, such that heat from the bottom of the crucible is conducted by the beams and/or radiated directly through the aperture formed by the at least two plates 18 when the at least two plates 18 are at least partially open. The weight carried by the beams can be transferred by extra structural beams or columns (not shown) that extend from the crystal growth apparatus 10. Similarly, referring to the support mechanism 14 of FIGS. 2A-2B and the support mechanism 14b of FIGS. 4A-4B, extra structural beams or columns (not shown) can be provided to support the weight of the crucible.

Referring to FIGS. 4A-4B, a support mechanism 14b is constituted by a block with a plurality of holes extending through the block, that is, a hollow block preferably made of graphite or similar material. By virtue of providing the hollow block, heat conducted by the hollow block will be conducted and radiated to a lesser extent as compared with a solid block.

According to the subject invention, the at least two plates 18 depicted in FIGS. 1, 2A-2B, 3A-3B, and 4A-4B preferably are arranged in an interlocking manner, so that at least portions of the plates overlap in a “sandwich” construction or a “staggered” construction, for example, in order to produce an aperture of a desired shape. Various shapes of apertures can be produced by the at least two plates 18, including but not limited to: square, rectangular, circular, parabolic, rhombic, and elliptical. Also, the subject invention encompasses any suitable shape including nonlinear shapes, as defined by the relationship y=f(x), where x and y refer to distances along the X-axis and Y-axis, respectively. Further, the at least two plates 18 may include one or more triangular sections, which define an aperture having the shape of a square, rectangle, or rhomus, for example. Preferably the at least two plates 18 are movable in a controlled manner so as to allow passage of radiant heat through the aperture, and thereby achieve thermal gradient profiles resembling a contour of the ingot being formed.

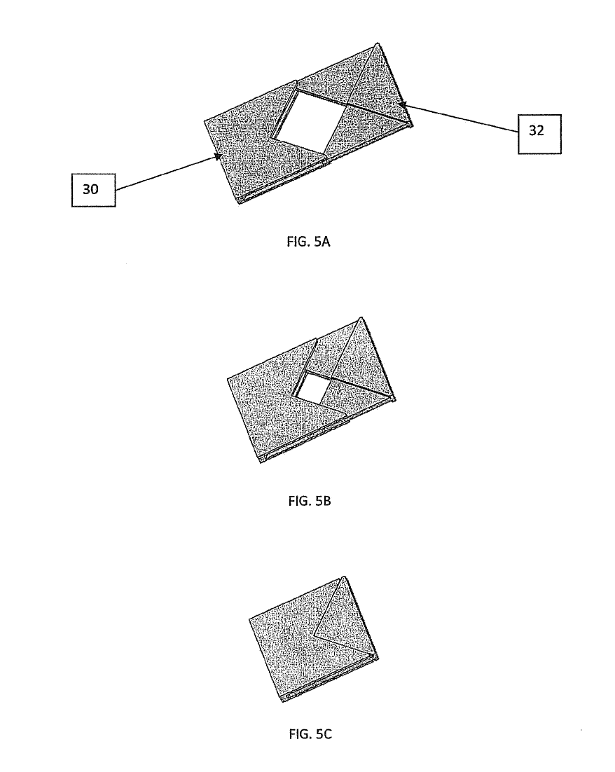

According to the subject invention, the at least two plates 18 can be moved between a fully closed position and a fully open position, with a plurality of discrete “partially open” positions formed between the fully closed and fully open positions. Referring to FIGS. 5A-5C and 5.1, at least two plates 30, 32 are configured to form a square aperture in the fully open and partially open positions. As shown in FIGS. 5A-5B and 5.1, the plate 32 includes triangular sections 32a, 32b that are sandwiched by the plate 30, which itself is divided into triangular sections 30a, 30b. In the fully closed position of FIG. 5C, the triangular sections 32a, 32b of the plate 32 are interlocked and engaged by the corresponding triangular sections 30a, 30b of the plate 30. In other words, according to the subject invention, the respective triangular sections of the plates 30, 32 will meet and fit together when the aperture is fully closed, as shown in FIG. 5C. For example, as shown in FIG. 5.1, the three layers of the plates 30, 32 have approximately mating triangular profiles, and thus a solid insulation pack can be formed in the fully closed position. The plates 30, 32 can be formed as one piece or multiple pieces, as long as similar geometrical features are provided. By virtue of the substantially identical triangular openings formed by the plates 30, 32, a square aperture can be formed in the fully open and partially open positions (see FIGS. 5A and 5B, respectively).

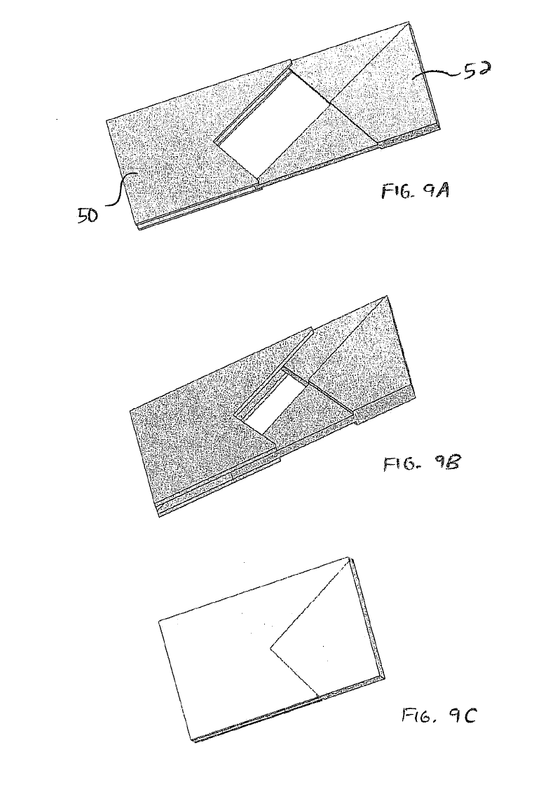

Alternatively, in other embodiments, by changing the shapes of the plates, the resulting aperture formed in the fully open and partially open positions can be rectangular or rhombic (see, e.g., FIGS. 9A-9C and FIGS. 11A-11C, respectively). In other words, by forming each of the plates with identical triangular openings, an aperture of the desired shape (for example, square, rectangular, or rhombic) can be formed when the plates are moved into a partially open or a fully open position.

Although the plate 30 is depicted as a single plate with separate top and bottom “sandwiching” portions, the plate 30 could be formed as a plurality of plates, and the total number of plates 30, 32 depicted in FIG. 5A, for example, could be more than two. As used herein, the term “interlocked” does not require or imply a sandwiched configuration, but simply refers to the plates 30, 32 being arranged to “fit together,” such that in the fully closed position of FIG. 5C, the plates 30, 32 are closed, and the aperture is substantially closed.

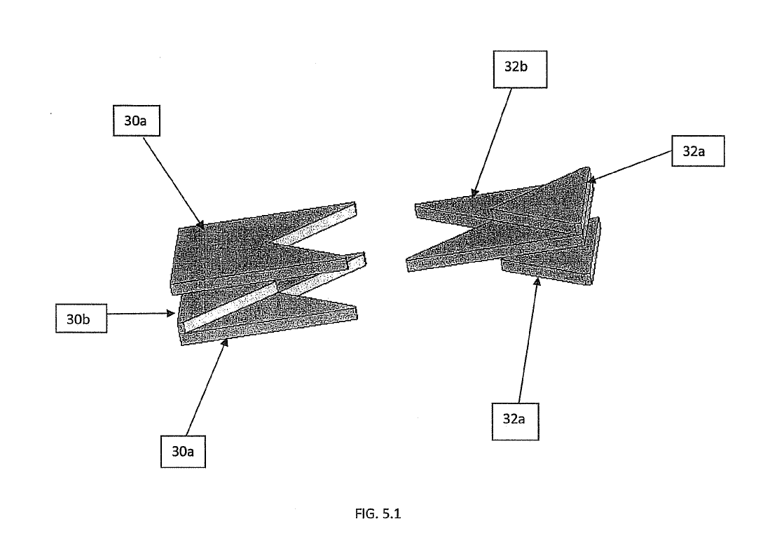

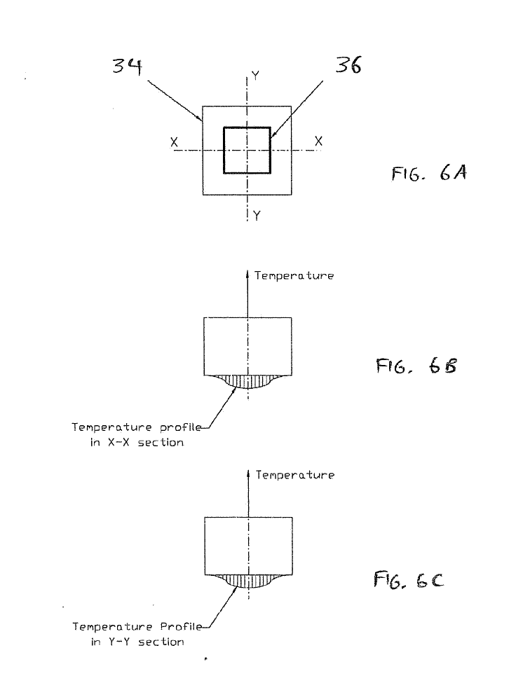

Referring to FIG. 6A, an ingot 34 being formed has a substantially square contour, and a heat release path 36 is generally square in shape when used with a square aperture. A square aperture produced by the plates 30, 32 depicted in FIGS. 5A-5C can be used with the square ingot shown in FIG. 6A, so as to approximately match the heat release path 36 of the ingot 34. FIGS. 6B and 6C depict thermal gradient profiles along the X-X and Y-Y sections, respectively, in FIG. 6A. The thermal gradient profiles of FIGS. 6B and 6C show lower temperatures toward a center of the ingot 34 being formed. Because of the lower temperatures at the center of the ingot 34, substantially faster cooling can be achieved at the center of the ingot 34, and thus an ingot with a convex profile can be generated. FIG. 7 depicts a temperature profile in an X-Y plane of the ingot 34 being formed, where the temperature is lowest at the center of the ingot 34, with gradually increasing temperatures toward the outside of the ingot 34.

Therefore, the plates 30, 32 depicted in FIGS. 5A-5C preferably are arranged under a crucible containing the ingot 34 having a square contour (see FIG. 6A), and the aperture formed by the plates 30, 32 is substantially square in shape and centered with respect to the ingot 34. By moving the plates 30, 32 from the fully closed position of FIG. 5C to the fully open position of FIG. 5A in discrete increments, it is possible to promote directional solidification by allowing radiant heat to pass through the aperture formed by the plates 30, 32, and form an ingot with a desired convex profile.

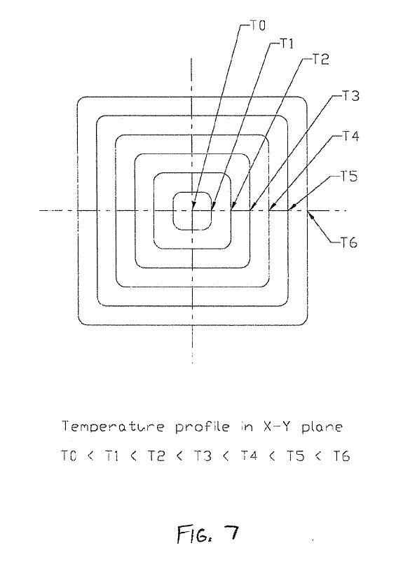

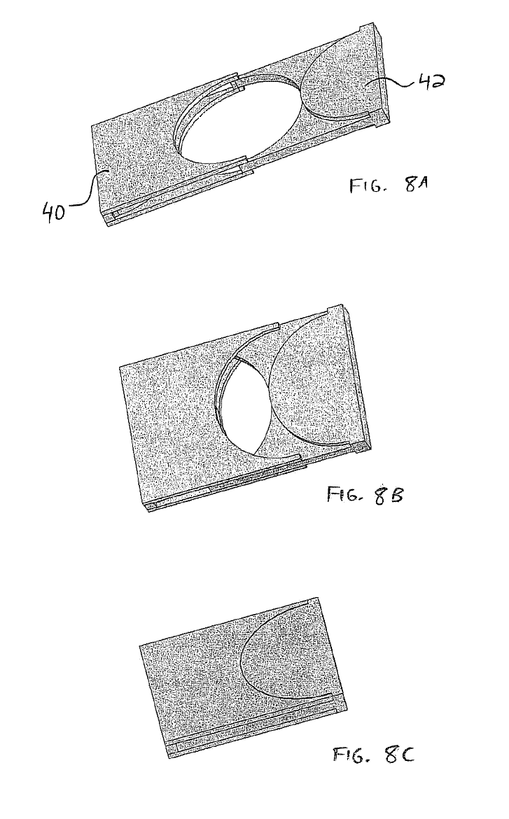

The at least two plates of varying shapes can be used to form apertures of different shapes. FIGS. 8A-8C depict at least two plates 40, 42 configured to form a circular aperture in a fully open position of FIG. 8A. As shown in FIG. 8B, in a partially open position, a substantially elliptical aperture is formed, and in the fully closed position of FIG. 8C, the plates 40, 42 are interlocked and engaged.

FIGS. 9A-9C depict at least two plates 50, 52 forming an aperture having a rectangular shape in a fully open position of FIG. 9A and a partially open position of FIG. 9B, where the at least two plates 50, 52 are interlocked and engaged in a fully closed position of FIG. 9C.

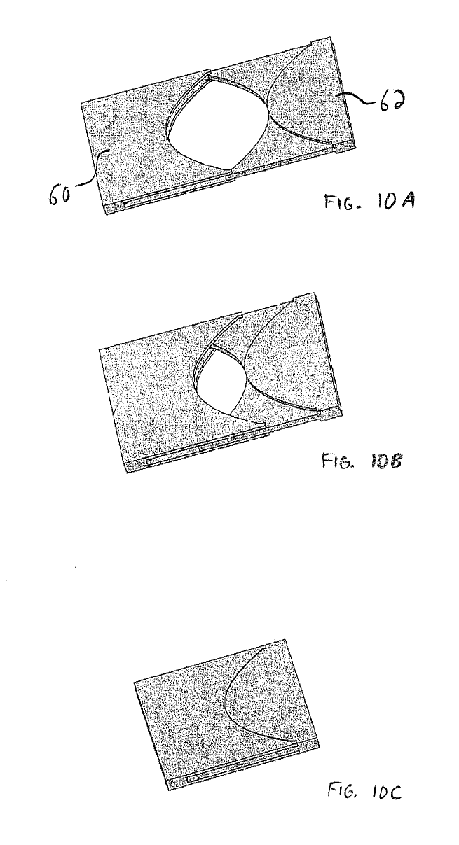

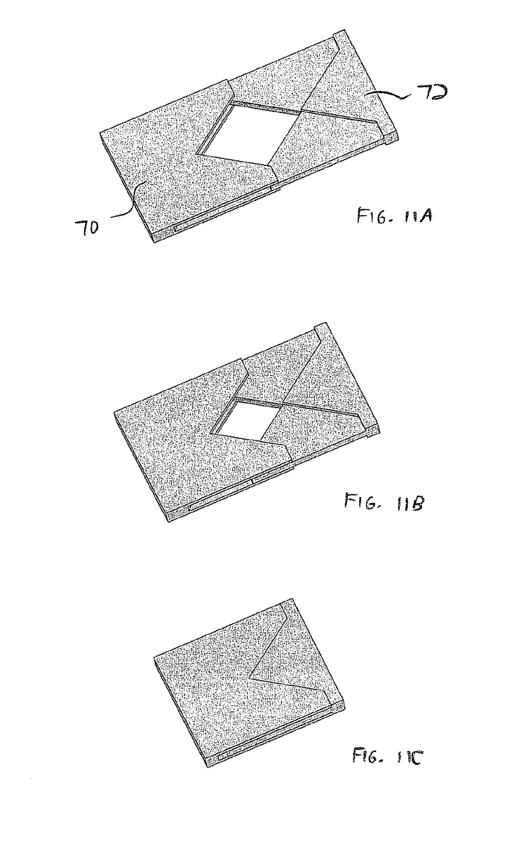

FIGS. 10A-10C depict at least two plates 60, 62 forming an aperture having a parabolic shape in a fully open position of FIG. 10A and a partially open position of FIG. 10B, where the at least two plates 60, 62 are interlocked and engaged in a fully closed position of FIG. 10C.

FIGS. 11A-11C depict at least two plates 70, 72 forming an aperture having a rhombic shape in a fully open position of FIG. 11A and a partially open position of FIG. 11B, where the at least two plates 70, 72 are interlocked and engaged in a fully closed position of FIG. 11C.

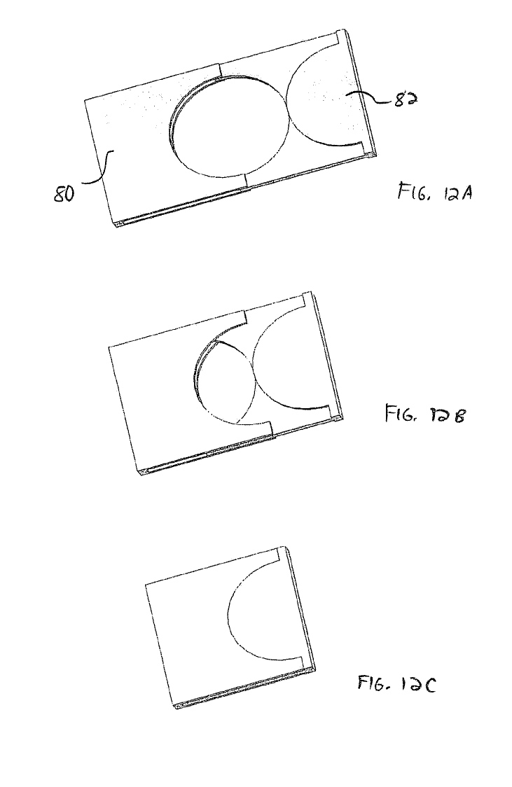

FIGS. 12A-12C depict at least two plates 80, 82 forming an aperture having a elliptical shape in a fully open position of FIG. 12A. As shown in FIG. 12B, a different substantially elliptical shape is formed in a partially open position. The at least two plates 80, 82 are interlocked and engaged in a fully closed position of FIG. 12C.

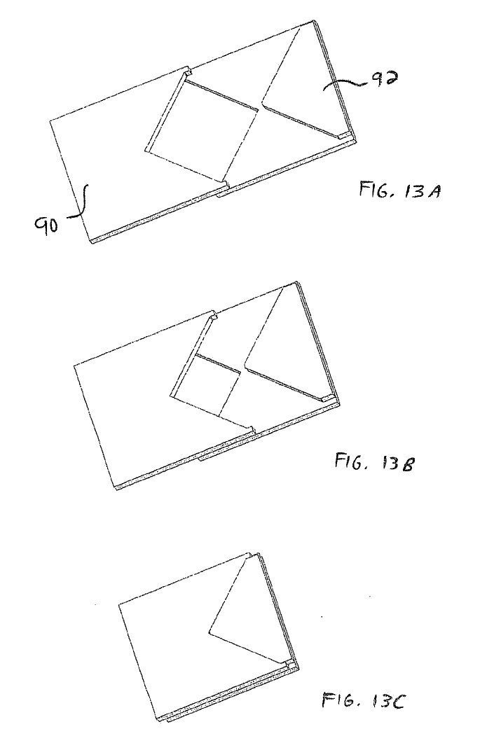

Referring to FIGS. 13A-13C, at least two plates 90, 92 are configured to form a square aperture in fully open and partially open positions (see FIGS. 13A and 13B, respectively). As shown in FIGS. 13A and 13B, the plate 90 includes portions that substantially overlap corresponding portions of the plate 92, so as to form a “staggered” construction, as distinguished from the “sandwich” construction depicted in FIGS. 5A-5C. As shown in FIG. 13C, in a fully closed position, the at least two plates 90, 92 are interlocked and engaged.

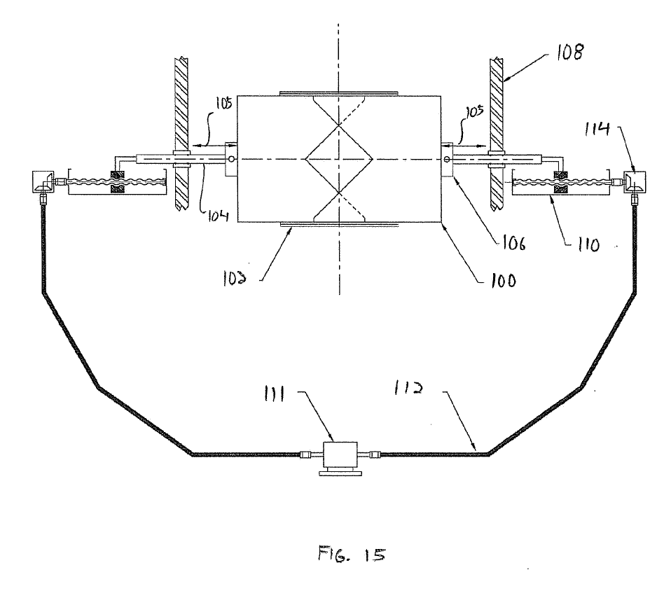

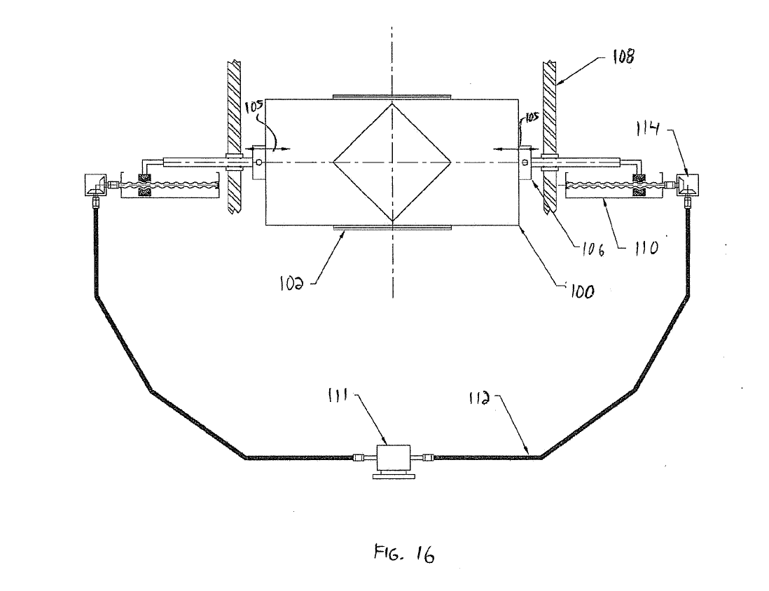

According to the subject invention, a drive mechanism is configured to drive the at least two plates with one degree of freedom. Referring to FIGS. 14-16, a drive mechanism is depicted for moving the at least two plates between a fully closed position (FIG. 14) and a fully open position (FIG. 16), where FIG. 15 corresponds to one of a plurality of intermediate partially open positions of the at least two plates. In FIGS. 14-16, reference number 100 is used to denote the at least two plates, where reference number 100 corresponds to reference number 18 in FIG. 1 and elsewhere in the figures. The at least two plates 100 depicted in FIGS. 14-16 can correspond to the plates 30, 32 depicted in FIGS. 5A-5C or the plates 90, 92 depicted in FIGS. 13A-13C, which form a square aperture, although other plates and other shapes of apertures can be used.

Referring to FIGS. 14-16, the at least two plates 100 can be mounted on a rail-guided slide system, including rails 102 and a shaft 104 for driving the at least two plates 100 with linear motion indicated by arrows 105. Each of the at least two plates 100 is provided with a connector 106 for mounting to the shaft 104. A screw drive 110 is linked to the shaft 104 for moving the shaft 104 as guided by a fixed support member 108, thus moving the at least two plates 100 linearly between the fully closed position of FIG. 14, through one or more discrete positions including the partially open position of FIG. 15, and to the fully open position of FIG. 16. The screw drive 110 is driven by a motor 111 that is operably connected to the screw drive 110 via a flex drive cable 112 and a gear box 114. Identical arrangements are provided to drive each of the at least two support plates 100. Because a single motor is provided, and the screw drives are configured to drive each respective plate with one degree of freedom, the at least two plates are moved in substantially equal amounts, and the drive mechanism is simplified as compared to arrangements in which the plates are separately driven or controlled.

The subject invention further relates to a device for controlling heat extraction from a crucible contained in a crystal growth apparatus that can include: at least two plates movable in a coordinated manner to form a symmetrical aperture substantially centered with respect to an ingot being formed in the crucible; and a drive mechanism configured to drive the at least two plates with one degree of freedom.

The subject invention further relates to a method for controlling heat extraction from a crucible contained in a crystal growth apparatus that can include steps of: providing a crucible for receiving a charge; heating and at least partially melting the charge contained in the crucible; providing at least two plates that are movable in a coordinated manner to form a symmetrical aperture substantially centered with respect to an ingot being formed in the crucible; and driving the at least two plates with one degree of freedom.

Although preferred embodiments of the invention have been described using specific terms, such description is for illustrative purposes only, and it is to be understood that changes and variations may be made without departing from the spirit or scope of the following claims.

### INCORPORATION BY REFERENCE

The entire contents of all patents, published patent applications and other references cited herein are hereby expressly incorporated herein in their entireties by reference.

What is claimed is:

1. A crystal growth apparatus, comprising:
a crucible for receiving a charge;
a support mechanism configured to support the crucible;
at least one heating element for heating and at least partially melting the charge; and
a device for controlling heat extraction from the crucible, comprising:
at least two plates being movable in a coordinated manner to form a symmetrical aperture substantially centered with respect to an ingot being formed in the crucible; and
a drive mechanism configured to drive the at least two plates with a single degree of freedom.

2. The crystal growth apparatus of claim 1, wherein the at least two plates are moved at the same rate so as to vary a size of the aperture.

3. The crystal growth apparatus of claim 1, wherein the at least two plates are movable between a fully closed position and a fully open position.

4. The crystal growth apparatus of claim 3, wherein the at least two plates are movable in a plurality of discrete positions between the fully closed position and the fully open position.

5. The crystal growth apparatus of claim 1, wherein the at least two plates are interlocking and overlapping.

6. The crystal growth apparatus of claim 1, wherein the at least two plates are configured to slide toward or away in approximately equal amounts from a bottom center of the crucible.

7. The crystal growth apparatus of claim 1, wherein the at least two plates form the aperture having a shape of a square, rectangle, circle, parabola, rhombus, or ellipse.

8. The crystal growth apparatus of claim 1, wherein the aperture has a shape defined by the relationship y=f(x), where x and y refer to distances along an X-axis and Y-axis, respectively.

9. The crystal growth apparatus of claim 1, wherein the at least two plates include triangular sections that form the aperture having the shape of a square, rectangle, or rhombus.

10. The crystal growth apparatus of claim 1, wherein the at least two plates are movable so as to allow passage of radiant heat through the aperture in a controlled manner, and achieve a convex gradient profile.

11. The crystal growth apparatus of claim 1, further comprising a crucible box for containing the crucible.

12. The crystal growth apparatus of claim 1, further comprising a diffusion plate arranged between the support mechanism and the at least two plates.

13. The crystal growth apparatus of claim 1, wherein the support mechanism comprises a solid block.

14. The crystal growth apparatus of claim 13, wherein the block includes a plurality of holes that extend through the block.

15. The crystal growth apparatus of claim 13, wherein the block is made of graphite.

16. The crystal growth apparatus of claim 1, wherein the support mechanism comprises a plurality of supports, beams, or columns.

17. The crystal growth apparatus of claim 1, further comprising a heat exchanger arranged in the crystal growth apparatus.

18. The crystal growth apparatus of claim 17, wherein the heat exchanger receives heat radiated from a bottom of the support mechanism.

19. The crystal growth apparatus of claim 1, wherein the crystal growth apparatus is a directional solidification furnace.

20. The crystal growth apparatus of claim 19, wherein the charge comprises silicon feedstock.

21. The crystal growth apparatus of claim 19, wherein the charge comprises silicon feedstock and a monocrystalline silicon seed.

22. A device for controlling heat extraction from a crucible contained in a crystal growth apparatus, the device comprising:
at least two plates being movable in a coordinated manner to form a symmetrical aperture substantially centered with respect to an ingot being formed in the crucible; and
a drive mechanism configured to drive the at least two plates with a single degree of freedom.

23. The device of claim 22, wherein the at least two plates are moved at the same rate so as to vary a size of the aperture.

24. The device of claim 22, wherein the at least two plates are movable between a fully closed position and a fully open position.

25. The device of claim 24, wherein the at least two plates are movable in a plurality of discrete positions between the fully closed position and the fully open position.

26. The device of claim 22, wherein the at least two plates are configured to slide toward or away in approximately equal amounts from a bottom center of the crucible.

27. The device of claim 22, wherein the at least two plates form the aperture having a shape of a square, rectangle, circle, parabola, rhombus, or ellipse.

28. The device of claim 22, wherein the aperture has a shape defined by the relationship y=f(x), where x and y refer to distances along an X-axis and Y-axis, respectively.

29. The device of claim 22, wherein the at least two plates include triangular sections that form the aperture having the shape of a square, rectangle, or rhombus.

30. A method for controlling heat extraction from a crucible contained in a crystal growth apparatus, comprising:
providing a crucible for receiving a charge;
heating and at least partially melting the charge contained in the crucible;
providing at least two plates that are movable in a coordinated manner to form a symmetrical aperture substantially centered with respect to an ingot being formed in the crucible; and
driving the at least two plates with a single degree of freedom.

31. The method of claim 30, wherein the driving step includes moving the at least two plates at the same rate so as to vary a size of the aperture.

32. The method of claim 30, wherein the at least two plates are movable between a fully closed position and a fully open position.

33. The method of claim 32, wherein the at least two plates are movable in a plurality of discrete positions between the fully closed position and the fully open position.

34. The method of claim 30, wherein the at least two plates are configured to slide toward or away in approximately equal amounts from a bottom center of the crucible.

35. The method of claim 30, wherein the at least two plates are movable so as to allow passage of radiant heat through the aperture in a controlled manner, and achieve a convex gradient profile.
